(19) United States
(12) Patent Application Publication
(10) Pub. No.: US 2026/0323989 A1
(43) Pub. Date: Oct. 15, 2026

(54) PLANAR GATE VERTICAL SILICON CARBIDE BASED SEMICONDUCTOR DEVICES WITH IMPROVED RECOVERY CHARACTERISTICS

(71) Applicant: Wolfspeed, Inc., Durham, NC (US)

(72) Inventors: Joohyung Kim, Cary, NC (US); Jae-Hyung Park, Apex, NC (US); Sei-Hyung Ryu, Cary, NC (US)

(21) Appl. No.: 19/179,393

(22) Filed: Apr. 15, 2025

(51) Int. Cl. H10D 30/66; H10D 8/50; H10D 30/01; H10D 62/10; H10D 62/60; H10D 84/00

(52) U.S. Cl. CPC H10D 30/662; H10D 8/50; H10D 62/107; H10D 62/127; H10D 62/60; H10D 84/144; H10D 30/0291

(57) ABSTRACT

A semiconductor device such as a MOSFET or IGBT comprises a semiconductor layer structure that comprises a drift layer and a plurality of well regions in the drift layer, the well regions extending to an upper surface of the semiconductor layer structure. The drift layer comprises a first region and a second region that has a higher peak doping concentration type than the first region. The second region of the drift layer comprises an implanted region and extends between adjacent well regions and underneath the well regions. The second region of the drift layer also comprises a plurality of openings, and the first region of the drift layer is exposed through the openings in the second region of the drift layer.

### FIELD

The present invention relates to semiconductor devices and, more particularly, to power semiconductor devices and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region that is electrically connected to the source terminal and a drain region that is electrically connected to the drain terminal are formed in the semiconductor layer structure and are separated by a channel region. A gate electrode that is electrically connected to the gate terminal is disposed adjacent the channel region and separated from the channel region by a thin oxide layer. A MOSFET may be turned on or off by setting a gate bias voltage that is applied to the gate electrode (through the gate terminal) to be above or below a threshold value. When the gate bias voltage exceeds the threshold value, the MOSFET is turned on (i.e., it is in its “on-state”), and current is conducted through the channel region between the source and drain regions. When the gate bias voltage is reduced below the threshold level, the MOSFET turns off and current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity. In other words, as used herein, the terms first conductivity type and second conductivity type refer to two different conductivity types.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate terminals may be on the top surface of the semiconductor layer structure and the drain terminal may be on the bottom surface of the semiconductor layer structure). The semiconductor layer structure may or may not include an underlying substrate such as a growth substrate. Vertical power semiconductor devices can typically block higher voltage levels than lateral power semiconductor devices.

Vertical power MOSFETs can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed channels that are formed in adjacent sidewalls of the gate trenches.

The semiconductor layer structure of a power semiconductor device typically includes an “active region” in which one or more functional semiconductor devices are formed. The active region acts as a main junction for blocking voltage during reverse bias (off-state) operation and providing current flow during forward bias (on-state) operation. The power semiconductor device may also have an edge termination structure such as, for example, guard rings or a junction termination extension, in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

FIGS. 1A and 1B are a schematic plan (top) view and a schematic cross-sectional view of a small portion of a conventional vertical silicon carbide power MOSFET 1 that has a planar gate structure. In the plan view of FIG. 1A, the upper dielectric layers, the gate electrodes and the source metallization are omitted to show the upper surface of the semiconductor layer structure. The dashed lines in FIG. 1A show where gate electrodes are formed on an upper surface of the semiconductor layer structure (with a gate dielectric layer separating the gate electrode from the semiconductor layer structure), and the dotted lines show where the source metallization extends through openings defined between adjacent gate electrodes to contact the semiconductor layer structure. FIG. 1B is a schematic cross-sectional diagram taken along the line 1B-1B of FIG. 1A with the gate electrodes and various upper metallization and dielectric layers of the power MOSFET that are omitted in FIG. 1A added for context.

As shown in FIGS. 1A-1B, power MOSFET 1 includes a heavily-doped n-type (n+) silicon carbide semiconductor substrate 10. A lightly-doped n-type (n⁻) silicon carbide drift layer 20 is provided on the upper surface of the substrate 10. The drift layer 20 includes a first region 22 that has a first peak doping concentration and a second region 24 that is on an upper surface of the first region 22. The second region 24 has a second peak doping concentration that is higher than the first peak doping concentration. A plurality of p-type well implant regions 30 are formed on/in upper portions of the n-type silicon carbide drift layer 20. Each well implant region 30 comprises a moderately doped p-type well region 32 (these well regions are also referred to herein as “p-wells”) and a heavily doped p-type well contact region 34. Channel regions 36 are formed in the upper outer portion of each p-well 32. A pair of heavily-doped (n⁺) n-type silicon carbide source regions 40 are formed in upper portions of each well implant region 30. As shown, the p-type well contact regions 34 may extend as deeply into the drift layer 20 as the p-wells 32 so that the well contact regions 34 directly contact the drift layer 20 in some cases. The second region 24 of the drift layer 20 is provided in between adjacent well implant regions 30 and also extends underneath the well implant regions 30. The n-type silicon carbide substrate 10, n-type silicon carbide drift layer 20, the well implant regions 30, and the n-type source regions 40 together comprise the semiconductor layer structure 50 of the MOSFET 1.

As shown in FIG. 1B, a plurality of gate oxide layers 60 are formed on the upper surface of the semiconductor layer structure 50, and a plurality of gate electrodes 62 are formed on the respective gate oxide layers 60 opposite the semiconductor layer structure 50. A plurality of intermetal dielectric patterns 64 cover the gate electrodes 62. Openings are defined in between adjacent intermetal dielectric patterns 64 that expose the upper surface of the semiconductor layer structure 50. A source metallization 90 is formed on the intermetal dielectric patterns 64 and within the openings in the intermetal dielectric pattern 64 so as to contact the heavily-doped n-type source regions 40 and the heavily-doped p-type well contact regions 34. A drain contact 92 is formed on the lower surface of the substrate 10.

The p-type channel regions 36 that are formed in the upper portions of the p-wells 32 electrically connect the n-type source regions 40 to the second region 24 of the drift layer 20 when a sufficient gate bias voltage is applied to the gate electrodes 62. When such a gate bias voltage is applied to the gate electrodes 62 (through the gate terminal of the MOSFET), current may flow from the source metallization 90 (which serves as or is electrically connected to the source terminal of the MOSFET) to the n-type source regions 40 through the channel regions 36 to the second region 24 of the drift layer 20. The current flows from the second region 24 of the drift layer 20 to the first region 22 of the drift layer 20 and into the substrate 10 and the drain contact 92, which serves as or is electrically connected to the drain terminal of the MOSFET.

Transistors used in power switching circuitry such as power MOSFET 1 generally need to be capable of conducting current bidirectionally. Accordingly, an anti-parallel diode is provided in conjunction with the transistor to allow bidirectional current flow. An anode of the anti-parallel diode is coupled to a drain of the MOSFET 1 and a cathode of the anti-parallel diode is coupled to a source of the MOSFET 1. This allows current to flow from the drain to the source in the MOSFET during a forward conduction mode of operation and from the source to the drain via the anti-parallel diode in a reverse conduction mode of operation. When switching between conducting and blocking, performance characteristics of the anti-parallel diode will determine the speed at which such a transition can occur and the switching losses that occur. It is generally desirable to minimize both the transition time between modes of operation and the switching losses.

While an external diode may be used as the anti-parallel diode, the same result can also be achieved using one or more built-in body diodes that are formed in the semiconductor layer structure 50. In particular, as shown in FIG. 1B, body diodes 70 are formed between the source metallization 90 and the drain contact 92. Using body diodes 70 to allow bidirectional current conduction saves space by foregoing the need for an external diode. However, the body diodes 70 may not be optimized for switching, which may result in increased switching times and/or increased switching losses.

### SUMMARY

Pursuant to some embodiments of the present invention, semiconductor devices are provided that comprise a semiconductor layer structure that comprises a drift layer having a first conductivity type that comprises a first region that has a first peak doping concentration and a second region that has a second peak doping concentration type that is greater than the first peak doping concentration and a plurality of well regions having a second conductivity type, the well regions extending to an upper surface of the semiconductor layer structure. The second region of the drift layer comprises an implanted region that is between adjacent well regions and underneath at least portions of the well regions. The second region of the drift layer also comprises a plurality of openings, and the first region of the drift layer is in the openings in the second region of the drift layer.

In some embodiments, the second region of the drift layer may be on top of the first region of the drift layer. In some embodiments, the first region of the drift layer may extend into the openings in the second region of the drift layer. In some embodiments, each well region may be part of a respective well implant region that has the second conductivity type, and each well implant region may further comprise a respective well contact region that has the second conductivity type, the well contact regions having higher peak doping concentration than the well regions. In some embodiments, each well contact region may be above and vertically overlapping a respective one of the openings in the second region of the drift layer. In some embodiments, a first of the well contact regions may be within a first of the well regions and may vertically overlap a first of the openings in the second region of the drift layer.

In some embodiments, a first area of a bottom of the first of the openings may be greater than a second area of a bottom surface of the first of the well contact regions. In other embodiments, a first area of a bottom of the first of the openings may be less than a second area of a bottom surface of the first of the well contact regions. In some embodiments, the first of the well regions may extend deeper into the semiconductor layer structure than the first of the well contact regions. In some embodiments, the first of the well contact regions may extend deeper into the semiconductor layer structure than the first of the well regions. In some embodiments, the first of the well contact regions may directly contact the first region of the drift layer. In some embodiments, the first of the well regions may also directly contact the first region of the drift layer.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode may be above an uppermost surface of the semiconductor layer structure.

In some embodiments, a portion of the drift layer that directly contacts a lower surface of a first of the well implant regions may comprise a first portion that is implanted with n-type dopants and a second portion that is not implanted with n-type dopants.

In some embodiments, the first region of the drift layer may comprise a plurality of upwardly-extending protrusions that are positioned underneath the respective well implant regions. In some embodiments, the upwardly-extending protrusions are not implanted with first conductivity type dopants.

In some embodiments, the second region of the drift layer may directly contact a bottom of the well region and the first region of the drift layer may directly contact a bottom of the well contact region. In some embodiments, the semiconductor device may be a silicon carbide based MOSFET.

Pursuant to further embodiments of the present invention, semiconductor devices are provided that comprise a semiconductor layer structure that comprises a drift layer having a first conductivity type and a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. The drift layer comprises an implanted portion that is implanted with n-type dopants and an un-implanted portion that is not implanted with n-type dopants, where both the implanted portion and the un-implanted portion directly contact a first of the well implant regions.

In some embodiments, the un-implanted portion of the drift layer may have a third peak doping concentration and the implanted portion of the drift layer may have a fourth peak doping concentration type that is greater than the third peak doping concentration. In some embodiments, each well contact region may directly contact the un-implanted portion of the drift layer. In some embodiments, the un-implanted portion of the drift layer may also directly contact a bottom of each well region.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode may be above an uppermost surface of the semiconductor layer structure.

In some embodiments, the un-implanted portion of the drift layer may comprise a plurality of upwardly-extending protrusions that are positioned underneath the respective well implant regions.

Pursuant to additional embodiments of the present invention, semiconductor devices are provided that comprise a semiconductor layer structure that comprises a drift layer having a first conductivity type and a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. A first region of the drift layer that directly contacts a middle portion of a bottom of a first of the well implant regions has a first doping concentration and a second region of the drift layer that directly contacts an outer portion of the bottom of the first of the well implant regions has a second doping concentration that is greater than the first doping concentration.

In some embodiments, the second region of the drift layer may be on top of the first region of the drift layer. In some embodiments, the first region of the drift layer may not be implanted with first conductivity type dopants and the second region of the drift layer may be implanted with first conductivity type dopants.

In some embodiments, the first region of the drift layer may directly contact each well contact region. In some embodiments, the first region of the drift layer may also directly contact a bottom of each well region.

In some embodiments, the second region of the drift layer may comprise a plurality of openings, and the first region of the drift layer may extend into the openings in the second region of the drift layer. In some embodiments, each well contact region may be above and vertically overlapping a respective one of the openings in the second region of the drift layer.

In some embodiments, each well contact region may directly contact the first region of the drift layer.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode is above an uppermost surface of the semiconductor layer structure.

Pursuant to yet further embodiments of the present invention, semiconductor devices are provided that comprise a semiconductor layer structure that comprises a drift layer having a first conductivity type that comprises a first region that has a first peak doping concentration and a second region that has a second peak doping concentration type that is greater than the first peak doping concentration and a plurality of well implant regions in an upper portion of the drift layer, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. The second region of the drift layer directly contacts bottom portions of at least some of the well regions and the first region of the drift layer directly contacts bottom portions of at least some of the well contact regions.

In some embodiments, the first region of the drift layer may comprise protrusions that extend upwardly through respective openings that are provided in the second region of the drift layer. In some embodiments, each well contact region may be above and vertically overlapping a respective one of the openings in the second region of the drift layer. In some embodiments, each well contact region may directly contact the first region of the drift layer.

In some embodiments, the second region of the drift layer may be on top of the first region of the drift layer.

In some embodiments, the first region of the drift layer may not be implanted with first conductivity type dopants and the second region of the drift layer may be implanted with first conductivity type dopants.

In some embodiments, the semiconductor device may further comprise a gate oxide layer on an upper surface of the semiconductor layer structure and a gate electrode on the gate oxide layer opposite the semiconductor layer structure, wherein a bottom surface of the gate electrode is above an uppermost surface of the semiconductor layer structure.

Pursuant to still further embodiments of the present invention, semiconductor devices are provided that comprise a semiconductor layer structure that comprises a drift layer having a first conductivity type that comprises a first region that has a first peak doping concentration and a second region that has a second peak doping concentration type that is greater than the first peak doping concentration and a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration. The first region of the drift layer comprises a plurality of upwardly-extending protrusions that are positioned underneath the respective well implant regions.

In some embodiments, the second region of the drift layer may comprise a plurality of openings, and the upwardly-extending protrusions of the first region of the drift layer may extend into the respective openings in the second region of the drift layer. In some embodiments, the second region of the drift layer may be on top of the first region of the drift layer. In some embodiments, each well contact region may be above and vertically overlapping a respective one of the openings in the second region of the drift layer. In some embodiments, the first region of the drift layer may directly contact each well contact region. In some embodiments, the first region of the drift layer may also directly contact a bottom surface of each well region.

In some embodiments, the semiconductor device may further comprise a gate oxide layer on an upper surface of the semiconductor layer structure and a gate electrode on the gate oxide layer opposite the semiconductor layer structure, and a bottom surface of the gate electrode is above an uppermost surface of the semiconductor layer structure.

Pursuant to other embodiments of the present invention, methods of forming a semiconductor device are provided. Pursuant to these methods, a preliminary drift layer having a first conductivity type is formed on a substrate. First conductivity type dopants are implanted into the first preliminary drift layer using a first ion implantation mask and second conductivity type dopants are implanted into the preliminary drift layer using a second ion implantation mask to convert the preliminary drift layer into a drift layer that has a first region that is not implanted with first conductivity type dopants and a second region that is implanted with second conductivity dopants and to form a plurality of preliminary well implant regions in an upper portion of the drift layer, each preliminary well implant region having a second conductivity type.

In some embodiments, the method may further comprise implanting second conductivity type dopants into the preliminary well implant regions using a third ion implantation mask to convert each preliminary well implant region into a well implant region that comprises a well region having a first peak doping concentration and a well contact region having a second peak doping concentration that is greater than the first peak doping concentration.

In some embodiments, the second region of the drift layer may comprise a plurality of openings. In some embodiments, the first region of the drift layer may comprise a plurality of upwardly-extending protrusions.

In some embodiments, the upwardly-extending protrusions in the first region of the drift layer may extend into the respective openings in the second region of the drift layer.

### BRIEF DESCRIPTION OF DRAWINGS

FIG. 1A is a schematic plan view of a small portion of a conventional power MOSFET.

FIG. 1B is a schematic cross-sectional diagram taken along the line 1B-1B of FIG. 1A with the gate electrodes and various of the upper metallization and dielectric layers of the power MOSFET that are omitted in FIG. 1A added for context.

FIG. 2 is a schematic graph illustrating the reverse recovery characteristics of a body diode in a MOSFET.

FIG. 3 is a graph that illustrates the distribution profile of minority carriers within the body diodes of two different MOSFETs during forward bias operation.

FIG. 4A is a schematic plan view of a top surface of a small portion of the semiconductor layer structure of a power MOSFET according to embodiments of the present invention.

FIG. 4B is a schematic cross-sectional diagram taken along the line 4B-4B of FIG. 4A with the gate electrodes and various of the upper metallization and dielectric layers of the power MOSFET added for context.

FIGS. 5A-5E are schematic cross-sectional diagrams illustrating an example method of fabricating the power MOSFET of FIGS. 4A-4B.

FIG. 6A is a plan view of the upper surface of a small portion of the semiconductor layer structure of a power MOSFET according to further embodiments of the present invention.

FIG. 6B is a schematic cross-sectional diagram taken along the line 6B-6B of FIG. 6A with the gate electrodes and various of the upper metallization and dielectric layers of the power MOSFET added for context.

FIGS. 7A-7D are cross-sectional views illustrating additional modified versions of the power MOSFET of FIGS. 4A-4B.

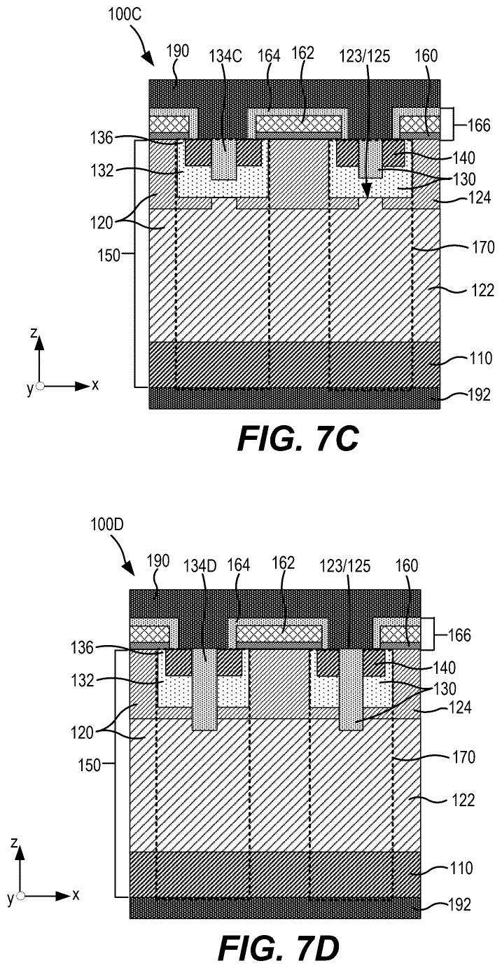

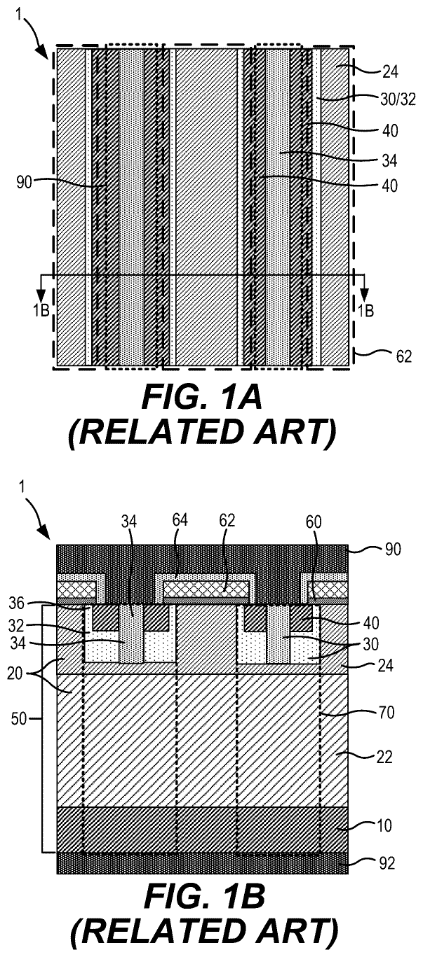

It will be appreciated that the thicknesses of various of the layers and regions in are not necessarily drawn to scale in the drawings.

### DETAILED DESCRIPTION

One parameter that is used to characterize the reverse recovery performance of a body diode is its “snappiness.” Generally speaking, a high degree of snappiness correlates to increased switching times and/or higher switching losses, both of which are undesirable. The body diodes used in many conventional power semiconductor devices may exhibit high degrees of snappiness.

FIG. 2 is a schematic graph that shows the forward current and voltage across a body diode of a MOSFET when the body diode of the MOSFET switches from forward conduction to reverse bias (blocking). Before time t0, the body diode is forward biased and thus conducting current from anode to cathode. The voltage across the body diode is thus around zero. During forward bias operation, excess minority carriers are injected into the drift layer of the MOSFET (and hence into the body diode) such that the drift layer contains excess minority carriers. At time t0, the body diode is switched from forward bias to reverse bias by changing the voltages supplied at the anode and cathode thereof. The current through the body diode thus begins to decrease as excess minority carriers decay. Because of the current flow from the excess minority carriers, the voltage across the body diode remains the same. At time t1, the current through the body diode switches from a positive current to a negative current. The voltage across the body diode continues to remain the same. As the stored excess minority carriers in the drift layer begin to decrease, a resistance of the drift region increases. Accordingly, at time t2 the voltage across the body diode begins to decrease, while the current continues to decrease. The depletion region begins to form at this time. At time t3, the reverse current through the body diode reaches its maximum value when very few excess minority carriers are left in the drift layer. At time t4, the negative voltage across the body diode reaches its peak value. The current through the body diode and the voltage across it continue to increase until time t5 when they stabilize at zero and the reverse voltage, respectively.

The time between when the current through the body diode passes through zero (t1) and reaches its negative peak value (t3) is designated as tₛ in FIG. 2. The time between when the current through the body diode reaches its negative peak value (t3) and when it recovers to 0.2*I_{RRM} (t4) is designated as t_{f} in FIG. 2 (where I_{RRM} refers to the current during reverse recovery). The ratio between t_{f} and tₛ (t_{f}/tₛ) is defined as a softness factor of the body diode. The softness factor is inversely correlated with snappiness of the body diode. Accordingly, a higher softness factor (and hence a lower snappiness) is desirable.

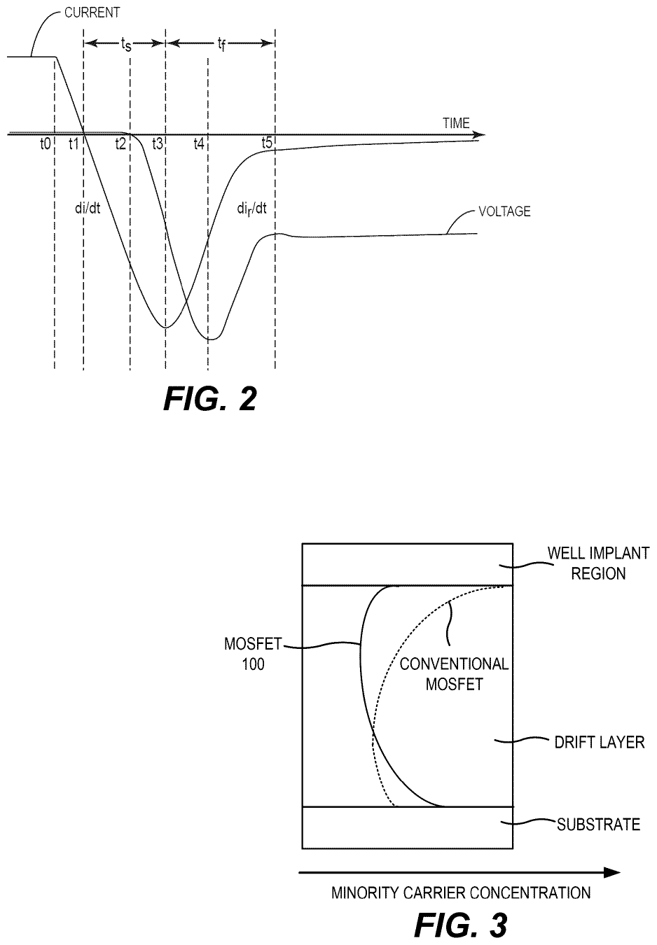

FIG. 3 is a schematic diagram that illustrates the distribution profile of minority carriers within both a conventional MOSFET (dashed line) and a MOSFET according to embodiments of the present invention (solid line) during forward bias operation. The dashed and solid lines in FIG. 3 illustrate the minority carrier concentration (the horizontal axis) as a function of depth (the vertical axis) within the drift layer, with the concentration increasing as the dashed/solid lines extend further to the right. Conventionally, those skilled in the art focus on optimizing the tradeoff between the breakdown voltage and the on-state resistance of a power MOSFET, and typically do not focus on the design of the body diode. As shown by the dashed line in FIG. 3, when this approach is taken, there tends to be a high concentration of minority carriers at the interface between the well implant region and the drift layer. When the concentration of minority carriers is high, it takes longer to sweep the minority carriers out of the upper portion of the drift layer, which delays formation of the depletion region. This prolongs tₛ, thereby increasing the snappiness of the body diode, which degrades the switching performance of the power MOSFET. Moreover, a conventional MOSFET may have a relatively low concentration of minority carriers at the interface between the drift layer and the substrate, as is also illustrated by the dashed line in FIG. 3. As the depletion region grows, these carriers may be swept out of the drift layer thus causing the depletion layer to punch through into the substrate. This will also degrade the performance of the MOSFET due to the sudden disappearance of the diffusion capacitance within the body diode.

As will be discussed in greater detail below, the power MOSFETs according to embodiments of the present invention may have body diodes that have the minority carrier distribution profile, during forward bias operation, that is shown by the solid line in FIG. 3. As shown, the minority carrier concentration in the upper portion of the drift layer is relatively low, which allows the minority carriers to be more quickly swept out of the upper portion of the drift layer when the MOSFET is switched to reverse bias operation, allowing the depletion region to form more quickly. This reduces the time tₛ, which decreases the snappiness of the body diode. The concentration of minority carriers near the interface between the drift layer and the substrate is increased, and is higher than the minority carrier concentration in the upper portion of the drift layer. This prolongs t_{f}, which also acts to decrease the snappiness of the body diode, which is desirable.

Pursuant to embodiments of the present invention, vertical power MOSFETs and other gate-controlled power semiconductor devices are provided that have body diodes that exhibit improved snappiness. As discussed above, the snappiness of a body diode may be reduced by reducing the concentration of minority carriers at the interface between the well implant region and the drift layer. However, since the minority carriers are injected into the drift layer from the well implant region, techniques that increase recombination of minority carriers in the upper portion of the drift layer may also reduce the number of minority carriers that flow to the lower portion of the drift layer. As is also discussed above, the snappiness of a body diode may also be reduced by increasing the concentration of minority carriers at the interface between the drift layer and the substrate. Thus, while reducing the concentration of minority carriers at the interface between the well implant region and the drift layer may beneficially reduce the snappiness of the body diode, it also may reduce the concentration of minority carriers at the interface between the drift layer and the substrate, which may increase the snappiness of the body diode.

As disclosed herein, pursuant to some embodiments of the present invention, power MOSFETs are provided that have first conductivity type drift layers that have a first region that has a first peak doping concentration and a second region that has a second peak doping concentration that is higher than the first peak doping concentration. These MOSFETs also include a plurality of second conductivity type well implant regions, where each well implant region comprises a well region having a third doping concentration and a well contact region having a fourth doping concentration that is higher than the third doping concentration. The first region of the drift layer may be a lower portion of the drift layer and the second region of the drift layer may be an upper portion of the drift layer. The second region of the drift layer may be formed by ion implantation, and may extend underneath the well implant regions. Openings may be provided in the second region of the drift layer. The first region of the drift layer may extend into these openings. While the first and second regions of the drift layer may both comprise n-type silicon carbide regions, the openings in the second region of the drift layer can readily be identified because these regions have the lower doping concentration associated with the first region of the drift layer and may be un-implanted regions, whereas the second region of the drift layer may comprise an implanted region. The openings in the second region of the drift layer may be provided underneath the respective well implant regions. For example, an opening may be formed underneath, and vertically overlapping, the well contact region of each well implant region.

While not intending to be bound by any particular theory of operation, it is believed that the well contact regions may be the primary supplier of the minority carriers that are present in the drift layer. Having the implanted second region of the drift layer extend underneath each well implant region acts to reduce the concentration of minority carriers in the drift layer for two regions. First, the damage to the crystal lattice from the ion implantation process used to form the second region of the drift layer generates recombination centers in the upper portion of the drift layer just below each well implant region. These recombination centers neutralize minority carriers. Second, the higher first conductivity type doping density of the second region of the drift layer (as compared to the first region of the drift layer) provides more majority carriers that can recombine with the minority carriers. Thus, by implanting the upper portion of the drift layer to provide the more highly-doped second region, the minority carrier concentration in the upper portion of the body diode during forward bias operation may be reduced, which helps reduce the snappiness of the body diode.

The openings in the second region of the drift layer, however, have the opposite effect, as these regions have lower n-type dopant concentrations and may not have ion implant damage. As such, minority carriers may more readily be injected into the body diode through these openings, and may persist within the drift region when the MOSFET switches to reverse bias operation. Again, while not intending to be bound by any particular theory of operation, it is believed that the more effective injection of minority carriers into the drift layer that is facilitated by the openings in the second portion of the drift layer may help increase the concentration of minority carriers at the interface between the drift layer and the substrate. While the openings may also increase the concentration of minority carriers at the interfaces between the well implant regions and the drift layer, the openings in the second region of the drift layer may be relatively small, and hence the remainder of the second region of the drift layer can act to reduce the concentration of minority carriers at the interfaces between the well implant regions and the drift layer. Thus, while the openings in the second region of the drift layer may increase the concentration of minority carriers at the interfaces between the well implant regions and the drift layer, it also increases the concentration of minority carriers at the interface between the drift layer and the substrate, and in some cases, this may be a favorable tradeoff that results in an overall reduction in the snappiness of the body diode.

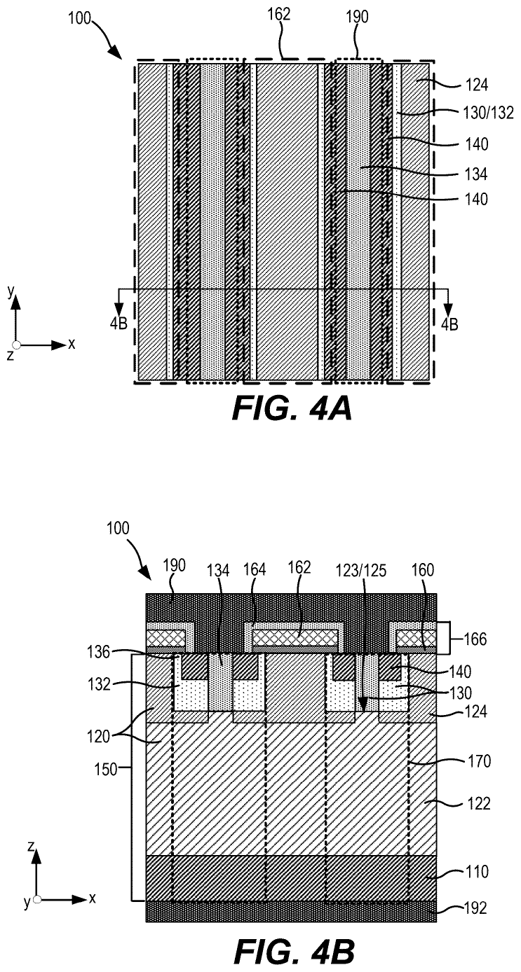

Example embodiments of power semiconductor devices according to embodiments of the present invention will now be described with reference to FIGS. 4A-7D. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs) and the like.

FIG. 4A is a schematic plan view of a top surface of a semiconductor layer structure of a planar gate vertical power MOSFET 100 according to embodiments of the present invention. Power MOSFET 100 has a so-called “stripe configuration” in which the well implant regions thereof are formed as continuous stripes that extend in parallel to each other within the semiconductor layer structure. While FIG. 4A illustrates the upper surface of the silicon carbide semiconductor layer structure of power MOSFET 100, the dashed lines show where three gate electrodes are formed above an upper surface of the semiconductor layer structure (with respective gate dielectric layers separating each gate electrode from the semiconductor layer structure), and the dotted lines show where a source metallization of MOSFET 100 contacts the semiconductor layer structure in regions in between adjacent gate electrodes. FIG. 4B is a schematic cross-sectional diagram of the power MOSFET 100 taken along line 4B-4B of FIG. 4A with the gate electrodes and upper metal and dielectric layers of power MOSFET 100 are added for context.

Referring to FIGS. 4A-4B, power MOSFET 100 includes an n-type silicon carbide semiconductor substrate 110 such as, for example, a single crystal 4H silicon carbide semiconductor substrate that is heavily-doped with n-type impurities. The n-type doping concentration of the substrate 110 may be, for example, between 1×10¹⁸ atoms/cm³ and 1×10²¹ atoms/cm³, although other doping concentrations may be used. Herein, the “doping concentration” of a semiconductor material refers to the number of dopant atoms that cause the semiconductor material to have a certain conductivity type (i.e., either n-type or p-type) that are present within a given volume of the semiconductor material (as measured using standard measurement techniques such as Secondary Ion Mass Spectrometry) minus the number of dopant atoms that have the opposite conductivity type that are present in the same region of the semiconductor material. Thus, for an n-type semiconductor material, references to the doping concentration refer to the concentration of n-type dopants minus the concentration of p-type dopants, and for a p-type semiconductor material, references to the doping concentration refer to the concentration of p-type dopants minus the concentration of n-type dopants. The substrate 110 may be any appropriate thickness (e.g., between 10 and 500 microns thick), and it will be appreciated that the substrate 110 will typically be much thicker than shown. The thickness of various other layers of power MOSFET 100 likewise may not be shown to scale in order to allow other portions of the device to be enlarged in the figures. The substrate 110 may be partially or fully removed in some embodiments.

A lightly-doped n-type silicon carbide drift layer 120 is provided on the upper surface of the substrate 110. The n-type silicon carbide drift layer 120 may have a first region 122 and a second region 124 that have different peak doping concentrations. In particular, the first region 122 may comprise the lower portion of the drift layer 120, and the second region 124 may be formed on an upper surface of the first region 122. The second region 124 of the drift layer 120 has a higher peak doping concentration than the first region 122 of the drift layer 120. The first (lower) region 122 of the n-type silicon carbide drift layer 120 may be formed by, for example, epitaxial growth on the silicon carbide substrate 110. The first region 122 of the drift layer 120 may have, for example, an n-type doping concentration of 1×10¹⁴ to 5×10¹⁶ dopants/cm³. The doping concentration may vary with the voltage blocking rating of the device, with devices having higher voltage blocking ratings typically having lower doping concentrations in the drift layer 120. For example, in a MOSFET having a voltage blocking rating of 10 kV, the doping concentration of the first region 122 of the drift layer 120 may be between 1×10¹⁴ to 5×10¹⁴ dopants/cm³, whereas in a MOSFET having a voltage blocking rating of 500-1200 V, the doping concentration of the first region 122 of the drift layer 120 may be between 1×10¹⁶ to 5×10¹⁶ dopants/cm³. The n-type silicon carbide drift layer 120 may have a thickness of, for example, 3-50 microns.

The second region 124 of the n-type silicon carbide drift layer 120 may be formed by, for example, a combination of epitaxial growth and ion implantation, or by ion implantation only, although other formation techniques are possible. When both epitaxial growth and ion implantation are used to form the second region 124 of the drift layer 120, an epitaxial growth process may be used to form a preliminary drift layer on the silicon carbide substrate 110 that has, for example, an n-type doping concentration that matches the doping concentration of the first region 122 of the drift layer 120 in the completed power MOSFET 100. An ion implantation process is then used to implant additional n-type dopants into an upper portion of the preliminary drift layer, thereby converting the upper portion of the preliminary drift layer into the second region 124 of the drift layer 120, thereby forming the drift layer 120 that has a first region 122 with a lower peak doping concentration and a second region 124 with a higher peak doping concentration. The peak doping concentration of the second region 124 of the drift layer 120, may be, for example, between 1.5 to 4.0 times higher than the peak doping concentration of the first region 122 of the drift layer 120. The second region 124 of the drift layer 120 may be a single continuous region or may comprise a plurality of spaced apart second regions 124 depending upon the design of power MOSFET 100.

As shown in FIG. 4B, the second region 124 of the drift layer 120 may be formed in between adjacent well implant regions 130 (discussed below) and may also extend underneath the well implant regions 130. The second region 124 of the drift layer 120 includes a plurality of “cutout” regions or “opening” 125 which are areas where the second region 124 of the drift layer 120 is not formed. The openings 125 may, for example, be formed underneath and vertically overlapping the well contact regions 134 (which are discussed below). The openings 125 may be formed by forming an ion implantation mask that covers certain areas of the preliminary drift layer during the ion implantation process used to form the second region 124 of the drift layer 120. Ions are not implanted into portions of the preliminary drift layer that are covered by the mask, and hence these portions of the preliminary drift layer are not further doped and hence remain part of the first region 122 of the drift layer 120. As such, the first region 122 of the drift layer 120 includes a plurality of upwardly-extending protrusions 123 that fill the respective openings 125 in the second region 124 of the drift layer 120.

A plurality of p-type well implant regions 130 are formed in upper portions of the n-type drift layer 120. As shown best in FIG. 4A, the well regions 130 may extend as stripes in a first direction (the y-direction in FIG. 4A), and may be spaced apart from each other in a second direction (here, the x-direction) that is perpendicular to the first direction. The well implant regions 130 extend to a predetermined depth into the drift layer 120 in a third direction (here, the z-direction) that is perpendicular to both the first direction and the second direction.

Each well implant region 130 may comprise a p-type well region 132 that has a third peak doping concentration and a p-type well contact region 134 that has a fourth peak doping concentration that is greater than the third peak doping concentration. In n-type power MOSFETs such as power MOSFET 100, the well regions 132 are often referred to as “p-wells” 132. Each p-well 132 may have a doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-wells 132 may be formed via ion implantation. The p-wells 130 typically have a doping concentration that varies with depth, with upper outer portions of each p-well 132 being less heavily doped than lower portions of the p-wells 130. Thus, each p-well 132 may have a graded p-type doping profile with the doping concentration increasing with increasing depth. As will be discussed in further detail below, the upper outer regions of the p-wells 132 act as channel regions 136 during on-state operation, and the doping concentration of the channel regions 136 is typically selected based on various performance characteristics of the power MOSFET, including a desired on-state resistance value. The lower portions of the p-wells 132 are typically more heavily doped p-type than the channel regions 136 to enhance the electric field blocking properties of the well implant regions 130.

The well contact regions 134 are formed within the respective well implant regions 130. Each well contact region 134 may extend to an upper surface of its well implant region 130 and may have a doping concentration of, for example, about 1×10¹⁹/cm³ to 1×10²¹ cm³, such as, for example, about 5×10¹⁹/cm³ to 5×10²⁰ cm³ or about 5×10¹⁹/cm³ to 1×10²⁰ cm³. Each well contact region 134 may directly contact the p-well 132 in which it is formed (which may be referred to herein as its “associated p-well”), and may extend as deep into the drift layer 120 as its associated p-well 132 in some embodiments. It will be appreciated, however, that embodiments of the present invention are not limited thereto. For example, in other embodiments the well contact regions 134 may not extend as deeply into the drift layer 120 as their associated p-wells 132 (in which case the well contact regions 134 may not directly contact the drift layer 120), while in other embodiments the well contact regions 134 may extend deeper into the drift layer 120 than their associated p-wells 132. Since the well contact regions 134 extend to the upper surface of the drift layer 120, they may directly contact the source metallization 190 (discussed below), thereby forming a low resistivity connection between the well implant regions 130 and the source metallization 190.

Heavily-doped n-type silicon carbide source regions 140 are formed in upper portions of the well implant regions 130. The source regions 140 may have a doping concentration of, for example, between 5×10¹⁸ cm⁻³ and 5×10²¹ cm⁻³. The source regions 140 are typically formed via ion implantation. In the depicted embodiment, the well contact regions 134 and the source regions 140 each extend as stripes in the y-direction, and hence two source regions 140 are formed in each well implant region 130. Embodiments of the present invention are not limited thereto. For example, in other embodiments, each well contact region 134 that is shown in FIG. 4A may be replaced with a series of much smaller well contact regions that are spaced apart from each other in the y-direction. In such an embodiment, a single continuous source region 140 is formed within each well implant region 130, and the smaller well contact regions 134 appear as islands within the continuous source region when the semiconductor layer structure of power MOSFET 100 is viewed from above.

The substrate 110, the drift layer 120 (including the first region 122 and the second region 124), the well implant regions 130 (including the p-wells 132 and the well contact regions 134), and the source regions 140 together comprise the semiconductor layer structure 150 of power MOSFET 100. FIG. 4A is a plan (top-down) view of the semiconductor layer structure 150.

As shown in FIG. 4B, a plurality of gate insulating layers 160 are formed on the upper surface of the semiconductor layer structure 150. Each gate insulating layer 160 may comprise, for example, a silicon oxide layer, although other insulating materials may be used. A plurality of gate electrodes 162 are formed on the respective gate insulating layers 160. Each gate electrode 162 may comprise, for example, a conductive material such as polysilicon, a silicide or a metal. A plurality of intermetal dielectric layers 164 may cover the respective gate electrode layers 162. Each intermetal dielectric layer 164 may comprise, for example, a silicon oxide layer. The combination of a gate insulating layer 160, the gate electrode 162 formed thereon, and the intermetal dielectric layer 164 covering the gate electrode may be referred to as a gate structure 166. As can be inferred from FIGS. 4A and 4B, the gate structures 166 extend on top of the semiconductor layer structure 150 as stripes in the y-direction. The upper surface of the semiconductor layer structure 150 (and, more particularly, the well contact regions 134 and the source regions 140) is exposed between each pair of adjacent gate structures 166. A source metallization 190 is formed over the intermetal dielectric layer 164 and on the exposed portions of the semiconductor layer structure 150 so that the source metallization 190 makes physical and electrical contact to the of the n-type source regions 140 and the p-type well contact regions 134 while being electrically insulated from the gate electrode 162. The source metallization 190 may comprise, for example, metals such as nickel, titanium, tungsten and/or aluminum, and/or alloys and/or thin layered stacks of these and/or similar materials. The source metallization 190 may also include a silicide layer that directly contacts the semiconductor layer structure top form an ohmic contact. A drain contact 192 may be formed on the lower surface of the substrate 110. The drain contact 192 may comprise, for example, the same or similar materials to the source metallization layer 190, and may form an ohmic contact to the silicon carbide substrate 110.

As discussed above, power MOSFETs such as power MOSFET 100 include body diodes that are connected in anti-parallel so that the MOSFET can conduct current bidirectionally. In particular, the body diodes allow current to flow from the source to the drain in a reverse conduction mode of operation.

As shown in FIG. 4B, a plurality of body diodes 170 are formed in power MOSFET 100. Each body diode 170 may comprise a PiN diode with the well implant region 130 acting as the p-type region, the substrate 110 acting as the n-type region, and the drift layer 120 acting as the i-type region (which is actually a lightly-doped n-type region).

As discussed above, the “snappiness” of a body diode is a measure of its reverse recovery characteristics. It is desirable to reduce both the switching time and the switching losses of a power MOSFET. Generally speaking, the higher the snappiness of the body diodes, the longer the switching times and the higher the switching losses. Thus, it is desirable to reduce the snappiness of the body diodes in a power MOSFET.

The body diodes 170 in power MOSFET 100 may exhibit reduced snappiness as compared to the body diodes in conventional power MOSFETs. As discussed above with reference to FIG. 3, the snappiness of a body diode may be reduced by reducing the concentration of minority carriers at the interface between the well implant region and the drift layer and/or by increasing the concentration of minority carriers at the interface between the drift layer and the substrate (at least to an extent that prevents depletion region punch-through into the substrate). However, since the minority carriers are injected into the drift layer from the well implant region, techniques that increase recombination of minority carriers in the upper portion of the drift layer may also reduce the number of minority carriers that flow to the lower portion of the drift layer. In other words, a tradeoff may exist with respect to the number of minority carriers that are injected into the drift layer.

The body diodes 170 of power MOSFET 100 may provide improved snappiness performance because, for example, they have the second region 124 of the drift layer 120 extend underneath the well implant regions 130 and because openings 125 are provided at selected locations within the second region 124 of the drift layer 120. As discussed above, the second region 124 of the drift layer 120 may be formed by ion implantation, which results in damage to the silicon carbide lattice in the portion of the drift layer 120 that is immediately below each well implant region 130. The ion implantation damage forms recombination centers that reduce the minority carrier concentration through recombination. In addition, the second region 124 of the drift layer 120 has an increased n-type doping concentration as compared to the remainder of the drift layer 120. This higher doping concentration acts to provide additional majority carriers that can recombine with the minority carriers. Thus, by implanting the upper portion of the drift layer 120 to provide the more highly-doped second region 124, the minority carrier concentration in the upper portion of the body diode 170 during forward bias operation may be reduced, which helps reduce the snappiness of the body diode 170.

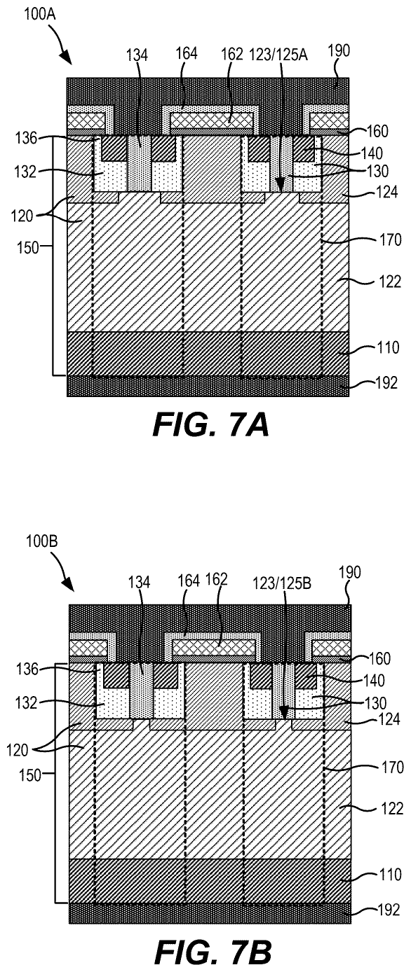

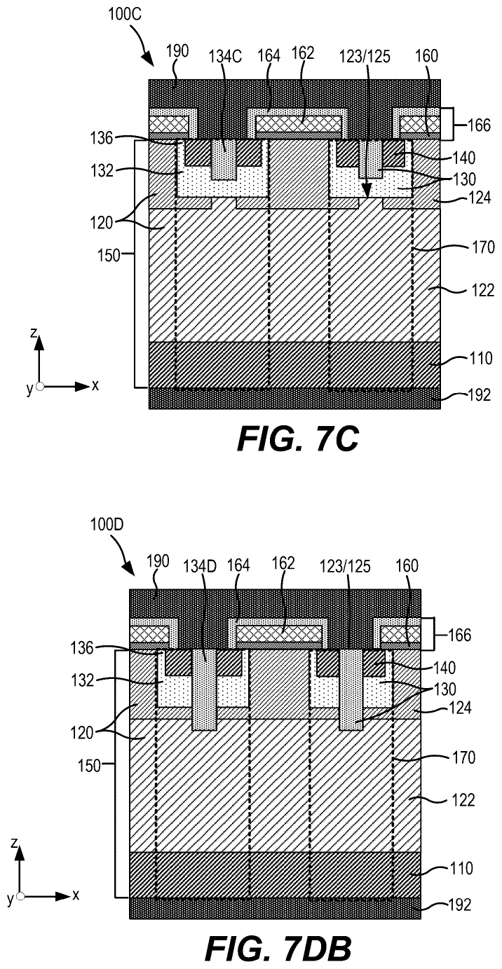

In FIG. 4B, the openings 125 are shown as having the same width in the x-direction as the well contact regions 134. It will be appreciated that embodiments of the present invention are not limited thereto. For example, as discussed below with reference to FIGS. 7A and 7B, in other embodiments, the openings 125 may have widths in the x-direction that are wider or narrower than the width of each well contact region 134. More generally, an area in the plane defined by the x-direction and the y-direction of each opening 125 may be greater than, equal to, or less than an area in the same plane of the bottom surface of the well contact region 134 that overlies each opening 125.

The second region 124 of the drift layer 120 also includes the plurality of openings 125, and the first region 122 of the drift layer 120 may extend into these openings 125. Moreover, in some embodiments, each well contact region 134 may extend through its associated p-well 132 to directly contact the first region 122 of the drift layer 120. This configuration allows minority carriers to more easily populate within the drift layer 120, which may beneficially increase the concentration of minority carriers at the interface between the drift layer 120 and the substrate 110, so that punch-through is avoided. While the openings 125 may also increase the concentration of minority carriers at the interfaces between the well implant regions 130 and the drift layer 120, the openings 125 in the second region 124 of the drift layer 120 may be relatively small, and hence the remainder of the second region 124 of the drift layer 120 can act to reduce the concentration of minority carriers at the interfaces between the well implant regions 130 and the drift layer 120. As a result, in overall improvement in performance may be obtained.

U.S. Pat. No. 11,769,827 (“the '827 patent”) discusses various techniques for reducing the snappiness of the body diodes in a silicon carbide based power MOSFET by reducing the concentration of minority carriers at the interfaces between the well implant regions and the drift layer. In particular, the '827 patent discusses (1) reducing the doping concentration of the well implant regions and (2) intentionally damaging an upper portion of the drift layer by implanting non-dopant elements such as argon, hydrogen and/or helium into the drift region in order to form recombination regions in the drift layer. The '827 patent explains that both of these techniques can reduce the minority carrier concentration in the upper portion of the drift layer. Notably, the approaches for improving the snappiness of the body diodes 170 that are disclosed herein are different than the approaches suggested in the '827 patent, as the power semiconductor devices according to embodiments of the present invention may have heavily-doped well contact regions 134 that extend to the bottom of the well implant regions 130 and because inactive dopants need not be (but can) be injected into the drift layer.

Referring again to FIGS. 4A-4B, pursuant to some embodiments of the present invention, semiconductor devices such as power MOSFET 100 are provided that comprises a semiconductor layer structure 150 that comprises a drift layer 120 having a first conductivity type (here n-type) and a plurality of well regions 132 having a second conductivity type (here, p-type) in the drift layer 120. The drift layer 120 comprises a first region 122 that has a first peak doping concentration and a second region 124 that has a second peak doping concentration type that is greater than the first peak doping concentration. The second region 124 of the drift layer 120 comprises an implanted region and extends between adjacent well regions 132 and underneath the well regions 132. The well regions 132 extend to an upper surface of the semiconductor layer structure 150. The second region 124 of the drift layer 120 comprises a plurality of openings 125, and the first region 122 of the drift layer 120 is exposed through the openings 125 in the second region 124 of the drift layer 120.

In some embodiments, the second region 124 of the drift layer 120 is on top of the first region 122 of the drift layer 120. The first region 122 of the drift layer 120 may extend into the openings 125 in the second region 124 of the drift layer 120.

In some embodiments, the semiconductor layer structure 150 may further comprise a plurality of well contact regions 134 that have the second conductivity type that are in the respective well regions 132, each well region 132 and the well contact region 134 within the well region 132 together forming a respective well implant region 130, where the well contact regions 134 have a higher peak doping concentration than the well regions 132. Each well contact region 134 may be above and vertically overlapping a respective one of the openings 125 in the second region 124 of the drift layer 120. A first of the well contact regions 134 is within the first of the well regions 132 and vertically overlaps a first of the openings 125 in the second region 124 of the drift layer 120. In some embodiments, a first area of a bottom of the first of the openings 125 is greater than a second area of a bottom surface of the first of the well contact regions 134. In other embodiments, the first area of the bottom of the first of the openings 125 may be less than or equal to the second area of the bottom surface of the first of the well contact regions 134. Herein a first region in a semiconductor layer structure vertically overlaps a second region in a semiconductor layer structure if an axis exists that is perpendicular to the major surfaces of the semiconductor layer structure that extends through both the first and second regions.

In some embodiments, the first of the well regions 132 extends deeper into the semiconductor layer structure 150 than the first of the well contact regions 134. In some embodiments, the first of the well contact regions 134 directly contacts the first region 122 of the drift layer 120. A bottom surface of the first of the well regions 132 may directly contact the second region 124 of the drift layer 120. In some embodiments, a portion of the drift layer 120 that directly contacts a lower surface of a first of the well implant regions 130 comprises a first portion 124 that is implanted with n-type dopants and a second portion 122 that is not implanted with n-type dopants.

The semiconductor device may further comprise a gate oxide layer 160 on an upper surface of the semiconductor layer structure 150 and a gate electrode 162 on the gate oxide layer 160 opposite the semiconductor layer structure 150, where a bottom surface of the gate electrode 162 is above an uppermost surface of the semiconductor layer structure 150.

The first region 122 of the drift layer 120 may comprise a plurality of upwardly-extending protrusions 123 that are positioned underneath the respective well implant regions 130. The second region 124 of the drift layer 120 may directly contact a bottom surface of the well region 132 and the first region 122 of the drift layer 120 may directly contact a bottom surface of the well contact region 134. The of upwardly-extending protrusions 123 of the first region 122 of the drift layer 120 thus may extend into the respective openings 125 in the second region 124 of the drift layer 120.

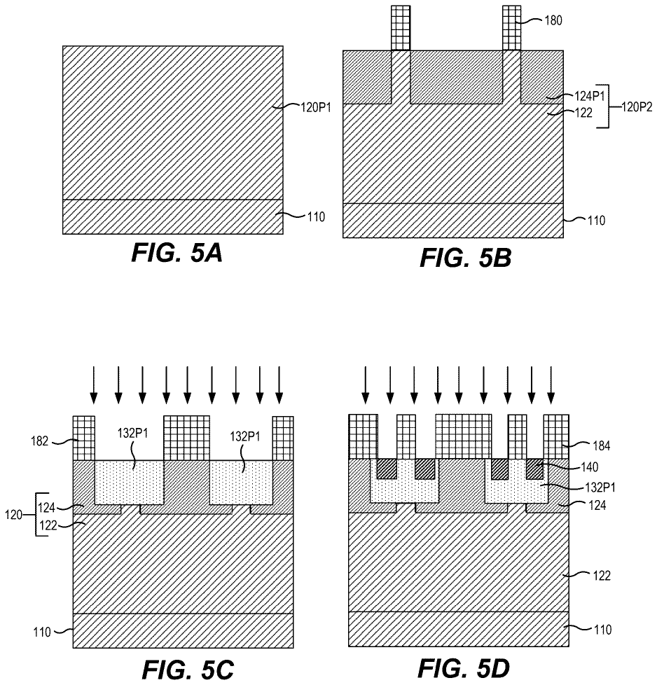

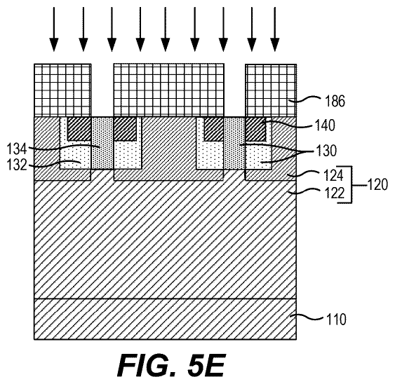

FIGS. 5A-5E are schematic cross-sectional diagrams illustrating a method of fabricating the power MOSFET 100 of FIGS. 4A-4B. The cross-sections of FIGS. 5A-5E are taken along line 4B-4B of FIG. 4A.

Referring to FIG. 5A, a first preliminary drift layer 120P1 is epitaxially grown on the heavily-doped n-type silicon carbide substrate 110. The first preliminary drift layer 120P1 may be an n-type silicon carbide epitaxial layer and may be doped n-type during the epitaxial growth process.

Referring to FIG. 5B, a first ion implantation mask (e.g., a silicon oxide mask) is formed on the upper surface of the first preliminary drift layer 120P1 and then patterned to form a first patterned mask 180 that exposes regions where the openings 125 in the second region of the drift layer 120 are to be formed. Next, an ion implantation process is performed to implant n-type dopants into the upper surface of the first preliminary drift layer 120P1. This ion implantation process converts the first preliminary drift layer 120P1 into a second preliminary drift layer 120P2 that includes a first region 122 that has a first doping concentration and a preliminary second region 124P1 that has a second higher doping concentration.

Referring to FIG. 5C, a second ion implantation mask (e.g., a silicon oxide mask) is formed on the upper surface of the second preliminary drift layer 120P2 and then patterned to form a second patterned mask 182 that exposes portions of the semiconductor layer structure 150 where the well implant regions 130 are to be formed. Next, an ion implantation process is performed to implant p-type dopants into the portions of the upper surface of the second preliminary drift layer 120P2 that are exposed by the second patterned mask 182 to form preliminary p-wells 132P1. The preliminary p-wells 132P1 are not formed as deep into the semiconductor layer structure 150 as the first region 122 of the second preliminary drift layer 120P2. Formation of the preliminary p-wells 132P1 converts the second preliminary drift layer 120P2 into the drift layer 120 having the first region 122 and the second region 124.

Referring to FIG. 5D, a third ion implantation mask (e.g., a silicon oxide mask) is formed on the upper surface of the second preliminary drift layer 120P2 and then patterned to form a third patterned mask 184 that exposes portions of the preliminary p-wells 132P1 where the source regions 140 are to be formed. Next, an ion implantation process is performed to implant n-type dopants into the portions of the upper surface of the preliminary p-wells 132P1 that are exposed by the third patterned mask 184 to form the source regions 140.

Referring to FIG. 5E, a fourth ion implantation mask (e.g., a silicon oxide mask) is formed on the upper surface of the semiconductor layer structure 150 and then patterned to form a fourth patterned mask 186 that exposes portions of the preliminary p-wells 132P1 where the well contact regions 134 are to be formed. Next, an ion implantation process is performed to implant p-type dopants into the portions of the upper surface of the preliminary p-wells 132P1 that are exposed by the fourth patterned mask 184 to form the well contact regions 134 and to convert the preliminary p-wells 132P1 into the p-wells 132 so that well implant regions 130 are formed that each comprise a p-well 132 and a well contact region 134.

In the above description, MOSFETs having a stripe configuration have been described where the well implant regions extend as stripes in the semiconductor layer structure. Additionally, in the above description, the gate electrodes of the MOSFETs extend as stripes on an upper surface of the semiconductor layer structure. It will be appreciated, however, that embodiments of the present invention are not limited to these configurations. For example, power MOSFET 100 could be modified to include a so-called “mesh” gate electrode where gate electrodes are provided that extend in both the y-direction and in the x-direction so that the gate signal can be distributed from one gate electrode to another gate electrode. In addition, the same techniques described above with respect to power MOSFET 100 may be implemented in power MOSFETs that have a so-called cell configuration. Power MOSFETs that have a cell configuration have well regions that are formed as spaced-apart islands within the semiconductor layer structure.

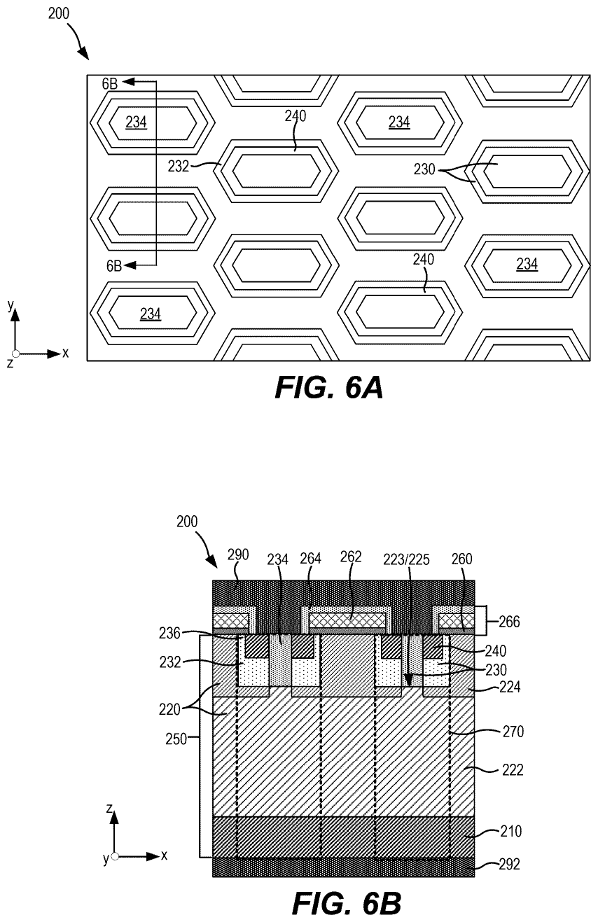

For example, FIGS. 6A-6B illustrate a power MOSFET 200 according to further embodiments of the present invention that has a cell configuration. FIG. 6A is a plan (top) view of the semiconductor layer structure 250 of power MOSFET 200 (i.e., the gate electrodes, upper dielectric layers and metallization layers are removed in the view of FIG. 6A), while FIG. 6B is a schematic cross-sectional view taken along line 6B-6B of FIG. 6A. In FIG. 6A, the dashed lines illustrate where the gate electrode is formed above the semiconductor layer structure 250, and the dotted lines illustrate the locations where a source metallization 290 of power MOSFET 200 directly contact the semiconductor layer structure 250. As shown by the dashed lines in FIG. 6A, a continuous gate electrode 262 extends above the semiconductor layer structure 250 and is separated from the semiconductor layer structure 250 by a continuous gate oxide layer (see FIG. 6B).

Referring to FIGS. 6A-6B, well implant regions 230 are formed in the upper surface of the semiconductor layer structure 250. Each well implant region 230 comprises a p-well 232 and a well contact region 234 that is formed in a central portion of the p-well 232. The well implant regions 230 each have an irregular hexagon shape when viewed from above. Each well implant region 230 comprises a p-well 232 that has an irregular hexagonal ring shape when viewed from above and a p-type well contact region 234 that is formed within the p-well 232. The well contact region 234 has a hexagonal shape when viewed from above. A source region 240 having an irregular hexagonal ring shape when viewed from above is formed in the upper portion of each well implant region between the outer portion of the p-well 232 and the well contact region 234.

As noted above, FIG. 6B is a cross-sectional view taken along line 6B-6B in FIG. 6A. As can be seen, the cross-section of FIG. 6B is identical to the cross-section of FIG. 4B except that all of the reference numerals are increased by 100. Thus, the description of FIG. 4B above applies equally to FIG. 6B, and hence FIG. 6B will not be described further here.

While power MOSFET 200 has hexagonally-shaped cells (e.g., hexagonally-shaped well implant regions), it will be appreciated that embodiments of the present invention are not limited thereto, and that the principles of the present disclosure apply equally to MOSFETs having cell configurations with well implant regions having other shapes including, for example, MOSFETs having triangular, rectangular (e.g., square), and octagonal shaped well implant regions.

FIGS. 7A-7D are cross-sectional views illustrating additional modified versions of the power MOSFET of FIGS. 4A-4B.

As shown in FIG. 7A, a power MOSFET 100A may be identical to power MOSFET 100 except that in power MOSFET 100A the openings 125A in the second region 124 of the drift layer 120 are larger than the openings 125 in power MOSFET 100. As such, each opening 125A exposes not only the bottom surface of its associated well contact region 134, but also exposes part of the bottom surface of its associated p-well 132 so that the first region 122 of the drift layer 120 directly contacts both the bottom surface of the well contact region 134 and the bottom surface of the p-well 132. Power MOSFET 100A may allow greater injection of minority carriers into the drift layer 120 during on-state operation.

As shown in FIG. 7B, a power MOSFET 100B may be identical to power MOSFET 100 except that in power MOSFET 100B the openings 125B in the second region 124 of the drift layer 120 are smaller than the openings 125 in power MOSFET 100. As such, each opening 125B does not expose the entirety of the bottom surface of its associated well contact region 134, and hence the second region 124 of the drift layer 120 may also be in direct contact with the bottom surface of the well contact region 134. Power MOSFET 100B may allow less injection of minority carriers into the drift layer 120 during on-state operation as compared to power MOSFET 100.

As shown in FIG. 7C, a power MOSFET 100C may be identical to power MOSFET 100 except that in power MOSFET 100C the well contact regions 134C do not extend as deeply into the semiconductor layer structure 150 as do the p-wells 132. This acts to reduce the concentration of minority carriers in the drift layer 120 during on-state operation as compared to power MOSFET 100.

As shown in FIG. 7D, a power MOSFET 100D may be identical to power MOSFET 100 except that in power MOSFET 100D the well contact regions 134D extend deeper into the semiconductor layer structure 150 than do the p-wells 132. As such, the well contact regions 134D may extend through the opening 125D in the second region 124 of the drift layer 120. The well contact regions 134D may extend all of the way through the respective openings 125D, as shown, or may only extend part of the way through the respective openings 125D. Having the well contact regions 134D extend deeper into the semiconductor layer structure 150 than the p-wells 132 acts to increase the injection of minority carriers into the drift layer 120 during on-state operation as compared to power MOSFET 100.

It will be appreciated that power MOSFETS 100C and 100D may be modified to have the larger openings 125A shown in FIG. 7A or the smaller openings 125B shown in FIG. 7B in other embodiments.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure that comprises:
a drift layer having a first conductivity type that comprises a first region that has a first peak doping concentration and a second region that has a second peak doping concentration type that is greater than the first peak doping concentration; and
a plurality of well regions having a second conductivity type, the well regions extending to an upper surface of the semiconductor layer structure;
wherein the second region of the drift layer comprises an implanted region that is between adjacent well regions and underneath at least portions of the well regions, and
wherein the second region of the drift layer comprises a plurality of openings, and the first region of the drift layer is in the openings in the second region of the drift layer.

2. The semiconductor device of claim 1, wherein the second region of the drift layer is on top of the first region of the drift layer.

3. The semiconductor device of claim 2, wherein the first region of the drift layer extends into the openings in the second region of the drift layer.

4. The semiconductor device of claim 3, wherein each well region is part of a respective well implant region that has the second conductivity type, and each well implant region further comprises a respective well contact region that has the second conductivity type, the well contact regions having higher peak doping concentration than the well regions.

5. The semiconductor device of claim 4, wherein each well contact region is above and vertically overlapping a respective one of the openings in the second region of the drift layer.

6. The semiconductor device of claim 5, wherein a first of the well contact regions is within a first of the well regions and vertically overlaps a first of the openings in the second region of the drift layer.

7-10. (canceled)

11. The semiconductor device of claim 6, wherein the first of the well contact regions directly contacts the first region of the drift layer.

12-13. (canceled)

14. The semiconductor device of claim 4, wherein a portion of the drift layer that directly contacts a lower surface of a first of the well implant regions comprises a first portion that is implanted with n-type dopants and a second portion that is not implanted with n-type dopants.

15. The semiconductor device of claim 4, wherein the first region of the drift layer comprises a plurality of upwardly-extending protrusions that are positioned underneath the respective well implant regions.

16. The semiconductor device of claim 15, wherein the upwardly-extending protrusions are not implanted with first conductivity type dopants.

17. The semiconductor device of claim 4, wherein the second region of the drift layer directly contacts a bottom of the well region and the first region of the drift layer directly contacts a bottom of the well contact region.

18-24. (canceled)

25. A semiconductor device, comprising:
a semiconductor layer structure that comprises:
a drift layer having a first conductivity type; and
a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration,
wherein a first region of the drift layer that directly contacts a middle portion of a bottom of a first of the well implant regions has a first doping concentration and a second region of the drift layer that directly contacts an outer portion of the bottom of the first of the well implant regions has a second doping concentration that is greater than the first doping concentration.

26. The semiconductor device of claim 25, wherein the second region of the drift layer is on top of the first region of the drift layer.

27. (canceled)

28. The semiconductor device of claim 26, wherein the first region of the drift layer directly contacts each well contact region.

29. (canceled)

30. The semiconductor device of claim 26, wherein the second region of the drift layer comprises a plurality of openings, and the first region of the drift layer extends into the openings in the second region of the drift layer.

31. The semiconductor device of claim 30, wherein each well contact region is above and vertically overlapping a respective one of the openings in the second region of the drift layer.

32-40. (canceled)

41. A semiconductor device, comprising:
a semiconductor layer structure that comprises:
a drift layer having a first conductivity type that comprises a first region that has a first peak doping concentration and a second region that has a second peak doping concentration type that is greater than the first peak doping concentration; and
a plurality of well implant regions, the well implant regions extending to an upper surface of the semiconductor layer structure and each well implant region comprising a well region having the second conductivity type and a first peak doping concentration and a well contact region having the second conductivity type and a second peak doping concentration, where the second peak doping concentration exceeds the first peak doping concentration,
wherein the first region of the drift layer comprises a plurality of upwardly-extending protrusions that are positioned underneath the respective well implant regions.

42. The semiconductor device of claim 41, wherein the second region of the drift layer comprises a plurality of openings, and the upwardly-extending protrusions of the first region of the drift layer extend into the respective openings in the second region of the drift layer.

43. The semiconductor device of claim 42, wherein the second region of the drift layer is on top of the first region of the drift layer.

44. The semiconductor device of claim 43, wherein each well contact region is above and vertically overlapping a respective one of the openings in the second region of the drift layer.

45. The semiconductor device of claim 44, wherein the first region of the drift layer directly contacts each well contact region.

46-52. (canceled)
